(19) United States
(12) Patent Application Publication
(10) Pub. No.: US 2011/0042133 A1
(43) Pub. Date: Feb. 24, 2011

(54) CARD GUARD

(76) Inventor: Alphonso Emerson Lythcott, Saint Albans, NY (US)

Correspondence Address: ALPHONSO EMERSON LYTHCOTT, 114-27 MEXICO STREET, SAINT ALBANS, NY, 11412, US

(21) Appl. No.: 12/856,214

(22) Filed: Oct. 26, 2010

Related U.S. Application Data
(60) Provisional application No. 61/274,004, filed on Aug. 13, 2009.

(51) Int. Cl. H05K 9/00

(52) U.S. Cl. 174/377

(57) ABSTRACT

The functionality or viability of this invention (Metallic Card Shield) is based on the properties of the natural chemical element Aluminum, which is known and proven to block or reflect both micro wave energy and radio wave energy. It is these two energies, the microwave and the radio wave, which are suspected of being the main culprits in the demagnetization of cards that employ a magnetic stripe to carry information. It is also by means of the radio wave that cards carrying an RFID enabled microchip may be hacked and their information read by unauthorized persons. Therefore it is the pure element Aluminum, which this invention seeks to capitalize upon and use to protect cards from having their information either erased or accessed by unauthorized persons.

### CROSS-REFERENCE TO RELATED APPLICATIONS

Not applicable.

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISC APPENDIX

Not Applicable

### BACKGROUND OF THE INVENTION

Metallic Card Shield is a new type of card folder, which will carry credit cards, debit cards, hotel room keys, identification cards, and any other wallet sized card that utilizes either a magnetic stripe or a microchip to carry or transmit information. The key folder industry is a huge one, but it's full potential has not been realized. It is estimated that every single day, hotels across the United States of America give out 18 million hotel room keys, the majority of which carry a magnetic stripe to encode information. Since hotel room keys are sometimes given out two at a time, this means at least 9 million hotel room key folders are given out along with these keys . . . every single day in the United States alone. But as of this moment, hotel room key folders are made of paper only and serve no other purpose other than to package a hotel guest's keys and advertise the hotel with decorative logos printed upon them. Metallic Card Shield is created for the purpose of making a card holder or folder that is more than merely decorative, but even protective of the sensitive information contained in myriad types of cards. In the case of hotels, the universally used conventional all paper folder cannot protect a hotel guest's room keys from being demagnetized . . . which leads to temporary lock outs from the rooms that were rented. This is an inconvenience that Metallic Card Shield was created to eliminate. In the case of ID badges and credit or debit cards, Metallic card Shield aims to go beyond the conventional decorative wallet or purse and actually protect the sensitive data contained in those cards from malicious hacking or unauthorized surveillance. Many ID badges and credit or debit cards posses RFID microchips with sensitive information like banking account numbers, medical or health information, etc. The industry for the latter usage of Metallic card Shield is largely uncharted territory since many individuals do not yet possess credit cards that contain microchips, nor do they carry at the time of this writing any national ID card that contains a microchip. But RFID credit cards and debit cards are spreading in usage. There is also a political force that aims to promulgate laws mandating the universal use of a national ID card in the United States. So to summarize, the hotel or hospitality side of the card key folder industry is very large, and the other potential areas of this industry (Credit and debit cards. ID cards) are potentially just as large, if not larger. College campuses also are adopting dormitory room keys that employ a magnetic stripe. So that is still another part of the industry that has great potential.

### BRIEF SUMMARY OF THE INVENTION

Metallic Card Shield is a special card holder or folder that utilizes the properties of the chemical element Aluminum to shield the card it carries (ID badges, hotel card keys, credit or debit cards, etc) from having its sensitive information erased by microwaves (or even radio waves) and from having that sensitive information maliciously read by an unauthorized individual. By accomplishing this function, this special card holder or folder serves valuable purposes to its user. One purpose is the protection of private sensitive information such as bank account numbers or medical history. Another purpose is to prevent cloning of the information on the card so as to prevent a hacker from being able to gain unauthorized access to a private place or area. Still another purpose is to protect the user of a card key from having the data on the magnetic stripe erased or scrambled, thus disabling the card key's ability to grant the user authorized access to private places or areas. Cell phone radiation (microwaves) is believed to scramble magnetic stripe information in card keys. Aluminum blocks microwave radiation. Meanwhile, cards that utilize a microchip might have RFID capabilities. RFID means radio frequency identification. A card carrying such a microchip, an RFID microchip . . . can be read at a distance using a scanner. But such a card shielding by an aluminum folder will disrupt the reception and transmission of radio wave signals to and from an RFID chip.

### BRIEF DESCRIPTION OF SEVERAL VIEWS OF THE DRAWING

FIG. 1 depicts the open card carrying folder made of aluminum metalized paper. Reference number 1 pertains to the inner side of one of the flaps of the folder, which is made of aluminum metalized paper. Reference number 2 refers to the other side of the folder, its other flap made of aluminum metalized paper. Reference number 3 refers to an inner fold made of aluminum metalized paper that serves to hold the card or card key in place. Reference number 4 refers to a depiction of a typical card which this invention would typically hold.

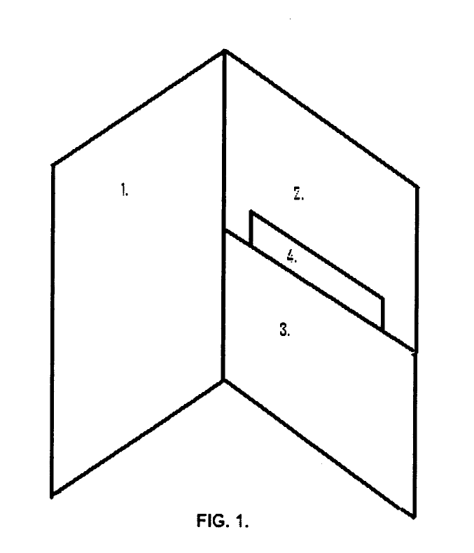

FIG. 2 depicts the same card folder design depicted in FIG. 1, except it is turned to an angle that makes one side of its outer jacket visible. Reference number 1 refers to the outside of the jacket. Reference number 2 refers to the inside of the jacket.

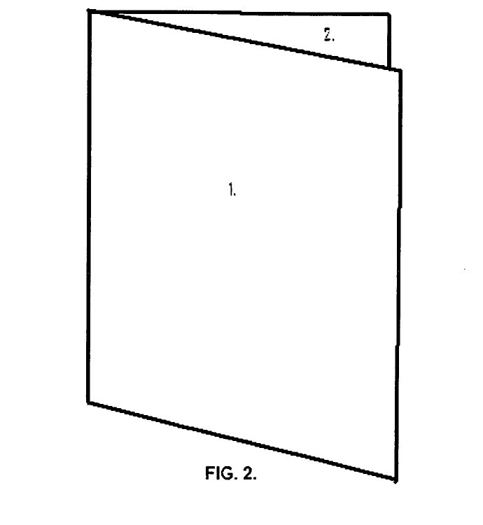

FIG. 3 depicts the open card carrying folder made of up of paper and aluminum foil lining. Reference number 1 pertains to the inner side of one of the flaps of the folder, which is made of paper and lined with aluminum on the inner side. Reference number 2 refers to the other side of the folder, its other flap made of paper and lined on the inside with aluminum. Reference number 3 refers to an inner fold made of paper lined with aluminum that serves to hold the card or card key in place. Reference number 4 refers to a depiction of a typical card which this invention would typically hold.

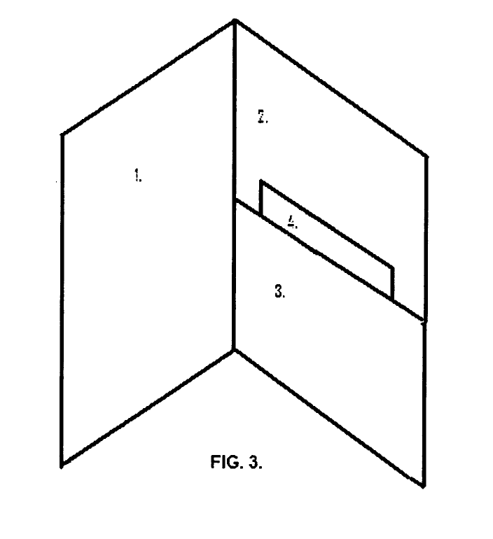

FIG. 4 depicts the same card folder design depicted in FIG. 3, except it is turned to an angle that makes one side of its outer paper jacket visible. Reference number 1 refers to the outside of the jacket which is made of paper. Reference number 2 refers to the inside of the jacket, which is lined with aluminum foil.

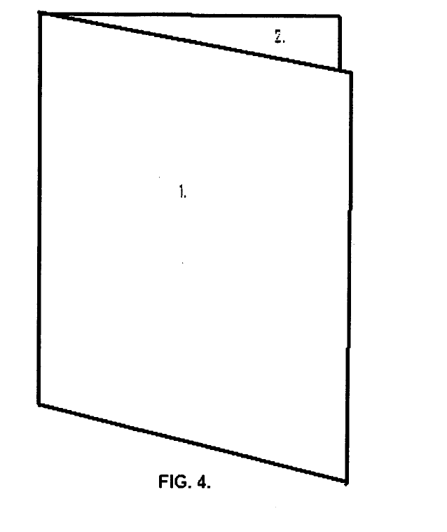

FIG. 5 depicts another shape of the Metallic Card Shield folder. This shape is more like a sleeve into which cards may be placed. Reference number 1 refers to the sleeve itself here which is made of aluminum metalized paper. Reference number 2 refers to a depiction of a typical card, such as a credit card or identification card that might be carried within this invention.

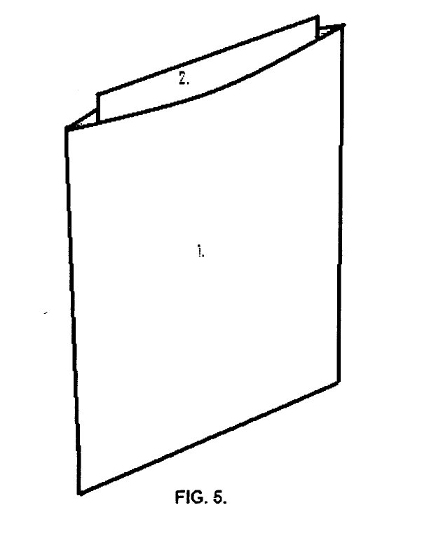

FIG. 6 depicts the same shape of the Metallic Card Shield folder depicted in FIG. 5. This shape is more like a sleeve into which cards may be placed. Reference number 1 refers to the sleeve itself here which is made of paper lined with aluminum foil. Reference number 2 refers to a depiction of a typical card, such as a credit card or identification card that might be carried within this invention.

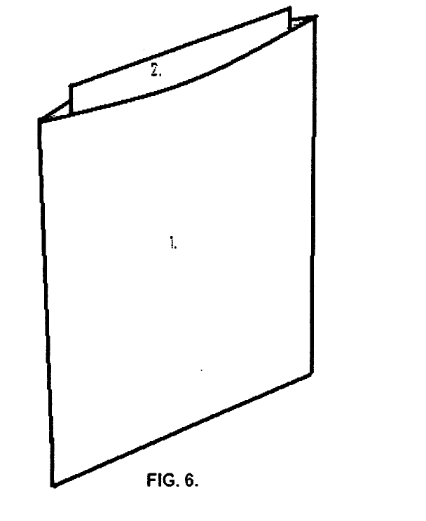

### DETAILED DESCRIPTION OF THE INVENTION

Metallic Card Shield will be constructed at least two different ways, including but not limited to; A) Aluminum foil lined paper or cardboard that is folded into the shape of a card folder or holder. B) Aluminum Metalized paper that is folded into the shape of a card folder or holder. Metalized paper is used commonly in labels and packaging to create a paper label or paper wrapping that has a metallic finish on at least one side of it. A scientific process fuses metal (usually Aluminum and/or other metals) to a sheet of paper. After that, the manufacture of Metallic Card Shield would require printing facilities to emblazon the metalized paper or aluminum lined paper with logos. Then a means of folding the paper into folders or holders would be needed. This means could be mechanical or human. This invention differs from conventional paper folders or holders because it serves a protective purpose for the information a card can contain or transmit. The former art . . . which was merely made of paper, serves only an ornamental purpose (i.e. it is merely a decoration). The new evolution of the art involves utilizing the properties of the chemical element Aluminum in blocking radio waves and/or microwaves in order to protect the card keys, credit cards, or ID badges that this folder or sleeve would hold. Without protection from those two forms of energy (the microwave and the radio wave), a card key can have its magnetic stripe erased of information, or have its RFID enabled microchip hacked by unauthorized persons. RFID refers to Radio Frequency Identification.

1. What I claim as my invention is the design of a paper and Aluminum folder or sleeve which is able to protect the card it carries from having its information erased or illegally accessed by means of microwaves and/or radio waves due to Aluminum's ability to block or reflect microwaves and radio waves.
